(19) United States
(12) Patent Application Publication
(10) Pub. No.: US 2014/0093690 A1
(43) Pub. Date: Apr. 3, 2014

(54) METHOD AND APPARATUS FOR LITHOGRAPHIC MANUFACTURE OF MULTI-COMPONENT POLYMERIC FIBER PLATES

(71) Applicants: Youngwook Noh, Gainesville, FL (US); Richard T. Farley, Gainesville, FL (US); James K. Walker, Gainesville, FL (US)

(72) Inventors: Youngwook Noh, Gainesville, FL (US); Richard T. Farley, Gainesville, FL (US); James K. Walker, Gainesville, FL (US)

(73) Assignee: NANOPTICS, INCORPORATED, GAINESVILLE, FL (US)

(21) Appl. No.: 13/985,793

(22) PCT Filed: May 31, 2012
(86) PCT No.: PCT/US12/40253

§ 371 Date: Aug. 15, 2013

Related U.S. Application Data
(60) Provisional application No. 61/491,491, filed on May 31, 2011.

(51) Int. Cl. G03F 7/00; B01L 3/00

(52) U.S. Cl. CPC G03F 7/0037; B01L 3/50857
USPC 428/156; 355/53; 430/322; 430/325

(57) ABSTRACT

Embodiments of the invention relate to microfabrication of three dimensional polymeric structures incorporating a large number of identical elements each having one or more materials. In specific embodiments, the structures are large area fiber optic plates and associated structures, wherein the fibers are precisely located relative to each other and can serve as optical readout, such as optical readout for high density microarrays of biomaterial and other chemicals or pharmaceuticals. A three-dimensional fiber optic plate can be fabricated by a lithographic process in which a 2D solid slice is produced by exposing a 2D layer of photocurable liquid to ultraviolet light. The cured layer is lowered and the process is repeated to build the plate layer by layer.

### CROSS REFERENCE TO RELATED APPLICATION

This application claims the benefit of U.S. Provisional Patent Application Ser. No. 61/491,491, filed May 31, 2011, the disclosure of which is hereby incorporated by reference in its entirety, including any figures, tables, or drawings.

### BACKGROUND OF INVENTION

In the last two decades, great progress has been made in the biological sciences by using microarray technology. This has enabled the parallel experimentation and diagnostic study of many thousands and even millions of samples of biomaterial. These arrays have provided a fast, reliable, and cost effective method of achieving results that would otherwise have required millions of independent experiments. These microarrays of biological or chemical materials have frequently been placed with high precision on glass slides, processed in some way, and read out by microarray readers, such as microscopes or other optical detectors. Alternatively, the arrays have been placed on glass fiber optic plates fabricated from millions of glass optical fibers, whose axes are normal to the plate surface. These fibers are efficient readout conduits of the luminescent light produced from the biomaterial located on the surface of the plate. The luminescent signals arriving at the back surface of the fiber optic plate have been detected by Charge Coupled Devices (CCDs) directly connected to the back of the plate. This technique offers a robust and efficient means of signal detection. However, these glass fiber optic plates can have distortions with the potential to give erroneous data. The high temperature and high pressure manufacturing process of the glass fiber plates creates alignment distortions in the fibers. Typically, these distortions amount to a few microns in the variations of pitch between fibers. In addition, there can be systemic gross and sheer distortions across large regions of the plate's surface. This magnitude of image distortion has been acceptable for microarrays of biomaterial whose spot diameter is greater than about 20 microns. Since many of the microarrays in the past have met this criterion, glass fiber optic plates have performed acceptably in these cases.

There is an increasing demand for next generation sequencing systems with much higher throughput, which will drive down the cost of diagnostics. This is exemplified by the vision of the National Institutes of Health “$1000 Human Genome Project”. In effect, this project requires that the biomaterial “spots” have diameters in the range 1 to a few microns and be located at a few microns from each other. If luminescent information is to be readout from these “spots”, the fiber optic plate should have the same few micron optical fiber pitch and alignment accuracy of less than one micron, relative to the “spots” across the surface of the plate. It does not appear that glass fiber optic plates can be cost effectively, if at all, made to the necessary precision.

Accordingly, there is a need for a method to be able to reproducibly achieve accurate fiber location in a fiber optic plate.

### BRIEF SUMMARY

Embodiments of the invention relate to a method and apparatus for lithographic manufacture of polymeric structures. Specific embodiments can use a microlithographic fabricative technique for the fabrication of precise plastic fiber optic plates. Such plastic fiber optic plates can be used for readout in, for example, high density, high throughput sequencing and diagnostic biomaterial systems. Embodiments pertain to a process and apparatus for fabrication of plastic fiber optic structures that have negligible image distortion and can be used for optical readout of very high density microarrays of biomaterial. A three-dimensional fiber optic plate can be fabricated by a lithographic process in which a 2D solid slice is produced by exposing a 2D layer of photocurable liquid to ultraviolet light. The cured layer is lowered and the process is repeated to build the plate layer by layer. The plate's structure, so formed, is composed only of the cladding material with voids in place of the final optical fiber's cores. The plate is removed from the lithographic fabrication equipment and excess unpolymerized material is removed. The plate is then baked to complete polymerization. The plate's precision array of voids are subsequently filled with prepolymer of the desired core material and polymerized in an oven. Large plates, composed of many millions of precisely located optical fibers, can be produced economically in this way. Specific embodiments of the present invention can use a manufacturing process to fabricate polymeric structures, such as plastic fiber optic plates (PFOP), incorporating one or more, and in a specific embodiment all five, of the following:
1) Manufacture of the interconnected cladding structure of the fiber optic plate by contact or scanning projection lithography, which establishes the high precision nature of the final product. A mask can be used to provide a patterned exposure on a photocurable liquid to form a polymeric layer that is adequately cured to provide structural stability. If desired, the initial layer can be lowered and subsequent layers built on each other until the desired thickness of the plate is achieved. In specific embodiments, the area of the fiber optic plate structure can be less than 1 square inch, in the range of 1 to 10 square inches, in the range of 5 to 10 square inches, and/or over 10 square inches. The lithographic system can create a precisely defined structure in photocurable liquid to a depth of up to 10 microns, up to 20 microns, and/or up to 30 microns, with spatial registration under 3 microns, under 2 microns, and/or under 1 micron. The photocurable liquid can contain an initiator and ultraviolet absorber, which together can limit the depth of curing to 10 microns, to 20 microns, and/or to 30 microns.
2) When an acceptable plate thickness has been achieved, normally 1 to several mm, the plate structure can be removed from the lithographic system. The plate structure can be washed with a solvent to remove unreacted monomer and less than fully polymerized material.
3) The plate structure, or plate/cladding structure, can be placed in a heated enclosure and fully cross-linked, polymerized, and/or cured.
4) The multiplicity of hollow cores within the cross-linked, polymerized, and/or cured cladding structure can he filled with a cross-linkable, polymerizable, and/or curable liquid prepolymer, and the structure placed in an oven with an appropriate temperature cycle to produce a fully cross-linked, polymerized, and/or cured solid core structure.
5) The large faces of the fully cross-linked, polymerized, and/or cured, plastic fiber optic plate structure can he cut and polished.

In an embodiment, the material forming the cladding structure can have a refractive index less than that of the core material. Preferably, the elements of the plastic fiber optic plate have a numerical aperture of at least 0.9, at least 0.95, at least 0.98, at least 0.99, at least 0.995, and/or at least 0.999. The most preferred materials provide a plastic fiber optic plate having a numerical aperture of unity (e.g. greater than 0.999). This large aperture ensures minimal cross-talk of light between the fibers and maximum signal to noise in the readout data. In specific embodiments, the diameter of the fiber is at least 2 microns, at least 3 microns, and/or at least a diameter below which the light intensity is severely limited by the number of fundamental modes of light propagation. Specific embodiments have diameters of the fibers in the range 3 to 50 microns, 50-100 microns, 100-500 microns, and/or 500 to 1000 microns, or higher.

Embodiments of the invention relate to a method, apparatus, and materials for forming a large area, three-dimensional plate structure that can convey an optical image from one face to another. A plurality of optical elements, each having a core surrounded by a cladding material can receive a portion of an optical image (a pixel) on a first face of the plate to a second face of the plate, and output the portion of the optical image (pixel) from the second face of the plate. The numerical aperture of the structure can be up to one. The limiting spatial resolution of the image is given by the fiber center to center pitch. In specific embodiments, the fiber center to center pitch is less than 5 microns, less than 6 microns, and/or less than 10 microns. In specific embodiments, the spatial registration of fiber axes, relative to each of a multiplicity of “spot” light sources, is less than 1 micron, less than 1.5 microns, and/or less than 2 microns. The image transmission is achieved with high contrast, high signal to noise, and high, or maximum, light collection efficiency from the “spot” light sources.

The foregoing has outlined, rather broadly, the features and technical advantages of specific embodiments of the present invention in order that the detailed description of the invention that follows may be better understood. The foregoing, and additional features and advantages of various embodiments of the invention will be described hereinafter. It should be appreciated by those skilled in the art that the conception and specific embodiments disclosed may be readily utilized as a basis for modifying or designing other structures for carrying out the same purposes of the embodiments of the present invention described. It should also be realized by those skilled in the art that such equivalent constructions do not depart from the spirit and scope of the invention. The features that are believed to be characteristic of the invention, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF DRAWINGS

FIG. 1 is a schematic depiction of a contact fabrication method in accordance with an embodiment of the invention.

FIG. 2 is a micro-photograph of the surface of the cured plastic cladding of the plate structure of a specific embodiment, where the holes in the cladding structure are 41 microns in diameter and the axes of the holes are positioned with an accuracy less than 1 micron relative to each other.

FIG. 3 shows the relationship between core and cladding refractive indices in accordance with various specific embodiments, which achieve a numerical aperture of unity for the optical fibers in the plate.

### DETAILED DISCLOSURE

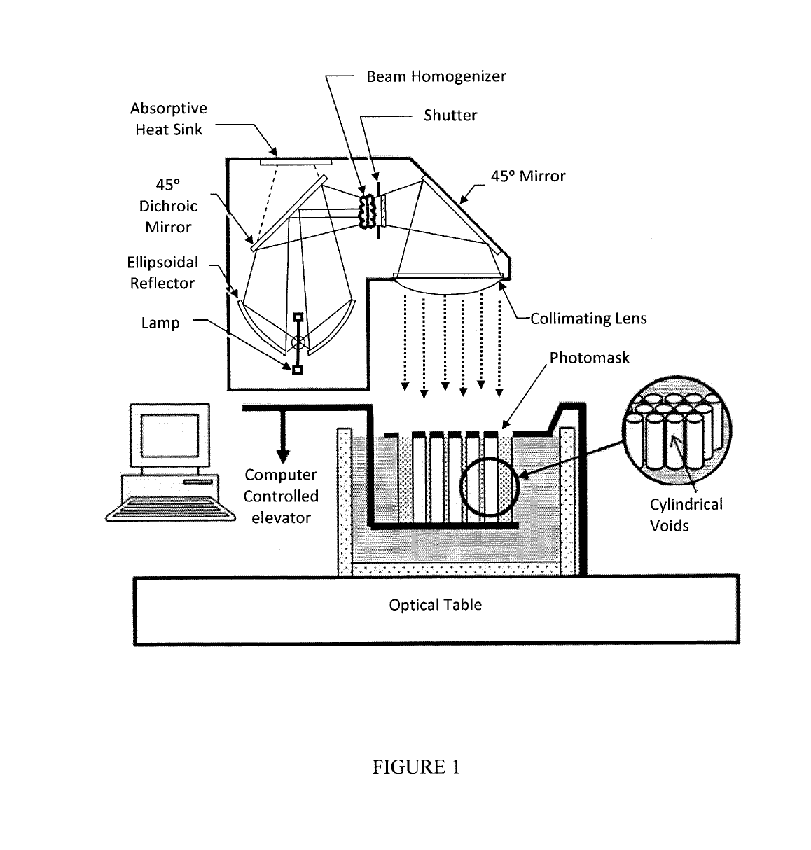

Embodiments of the present invention pertain to a method and apparatus for lithographic manufacture of polymeric structures. Specific embodiments can be used to fabricate large area, 3D polymeric plate structures. Embodiments of the plate structures can transmit high resolution optical images with negligible distortion and high efficiency from one end of the plate to the other. Embodiments of a fabrication method in accordance with the invention can incorporate one or more, and in a specific embodiment all five, of five stages. The first stage involves lithographic production of the cladding structure of the final product. FIG. 1 is a schematic depiction of an embodiment of a lithographic fabrication apparatus that can be used to implement specific embodiments of a method of fabrication. In a specific embodiment, the apparatus schematically depicted in FIG. 1 can be used to implement contact lithography. A variety of illumination sources can be used to expose the material through a mask (photomask). Such exposure can cross-link, polymerize, and/or cure the material to an extent that sufficient structural integrity is achieved to proceed with the remainder of the manufacturing process. In a specific embodiment, a conventional illumination system, such as a Flood Exposure Source from Oriel Instruments, can be used as the near UV (350-450 nm) beam source. FIG. 1 shows a collimating lens that can also be optically used to create parallel paths for the exposing radiation. This illuminator irradiates samples with a 152×152 mm collimated beam with a divergence of 1.8° half angle. A 500 Watt mercury arc lamp provides up to 38 mW per square cm at the mask. In a specific embodiment, as shown in FIG. 1, the illumination from the lamp can be guided to the collimating lens via an ellipsoidal reflector, a 45° dichroic minor, a beam homogenizer, a shutter, and a 45° mirror. Other arrangements can also be utilized to supply the illumination. A band pass filter to selectively pass only the 365 nm (i-line) can optionally be used in the illuminator.

Referring to FIG. 1, a glass/chrome mask (photomask), manufactured by Photo Sciences Inc., Torrance, Calif., is shown located in the UV beam. The mask pattern is a 2-D array of chromium circular spots. The spots can have a diameter appropriate for the application. In specific embodiments, the spots can have diameters in the range of 3 to 5 microns, in the range 5 to 10 microns, in the range 10 to 50 microns, in the range 50 to 100 microns, and/or in the range 100 to 500 microns, or larger. In one embodiment, the face of the mask with the 2-D array of spots can be coated with a perfluorinated polymer layer to minimize adhesion of the polymerizing monomer to the mask. The thickness of the perfluorinated layer can be, for example, in the range of 0.1 to 5 microns. Other mask patterns can also be utilized. The UV light is transmitted through the clear regions of the mask corresponding to those regions in the final product where cladding polymer is desired. The light exposes the monomer that is located above the platform. The vertical position of the platform is controlled by the computer. At the beginning of the exposure, the platform is positioned such that there is a depth of about 5 to 50 microns, preferentially 10 to 30 microns, of polymerizable monomer between the mask and platform.

In an embodiment of the invention, the mask, photocurable liquid and bath are enclosed in a container within which there is an inert gas.

The layer of photocurable liquid is exposed to the UV beam until it is cured, or at least sufficiently cured, to ensure its mechanical integrity. The computer then closes the shutter in the illuminator, and lowers the platform. This lowering process is a programmed sequence of vertical steps beginning with 0.1 micron increments to slowly overcome the stiction force between the photomask and the polymer material. This movement carries the cured layer down 5 to 50 microns, preferentially 10 to 30 microns, until a second fresh layer of photocurable liquid is formed. The computer opens the shutter and the second layer of photocurable liquid is then polymerized. This process can be repeated layer by layer until the desired thickness of the structure has been fabricated.

Various photocurable compositions can be used, as many such photocurable compositions are well known in the art of photopolymer chemistry. One set of possible components is:

### 1. Monomer: 1,6-hexanediol diacrylate; CAS #13048-33-4

In general, monomers or oligomers, or mixtures thereof, may be composed of mono or multi functional acrylates or methacrylates. In specific embodiments, partially and per-fluorinated monomers can be used, and can provide low refractive index polymers.

### 2. Light Initiator: 2-hydroxy-2-methylpropiophenone; CAS #7473-98-5

Appropriate photoinitiators at a concentration of, for example, 0.001 to 5.0%, can be used to activate the polymerization of the photocurable liquid by incident light in the band of wavelengths transmitted through the mask. Another example of an appropriate photoinitiator is Irgacure 819 (bis(2,4,6-trimethylbenzoyl)-phenylphosphineoxide) from CIBA.

### 3. UV Absorber: 2-hydroxy-4-(octyloxy)benzophenone; CAS #1843-05-6

The UV absorber can be used to control the penetration depth of the light through the photocurable liquid to be comparable, or at least related to, the depth of each layer used in the fabrication process. In specific embodiments, the concentration of the absorber can be in the range 0.001 to 10% wt/wt.

When the desired plate thickness has been achieved, the plate structure is removed from the lithographic system. The plate structure can be washed with a solvent to remove unreacted monomer and/or less than fully polymerized material. Specific embodiments can use solvents such as methanol, methyl ethyl ketone, or other weak solvents, or combinations thereof. It has been found to be advantageous to perform the solvent washing in an ultrasound activated bath.

The plate can be removed from the bath and carefully dried. The solid structure can be composed primarily of polymer, some oligomer, and a small amount of dissolved monomer. It is desirable to achieve the full structural strength corresponding to greater than 99% cross-linked, polymerized, and/or cured polymer. In order to achieve greater than 99% cross-linked, polymerized, and/or cured polymer, the plate can be subjected to a final curing cycle. For this purpose, the plate structure can be placed in a heated enclosure for 10 hours at 50° C., followed by 24 hours at 65° C. Other final curing cycles can also be implemented. After the final curing cycle, the cladding structure can be considered to be fully cross-linked, polymerized, and/or cured and structurally stable.

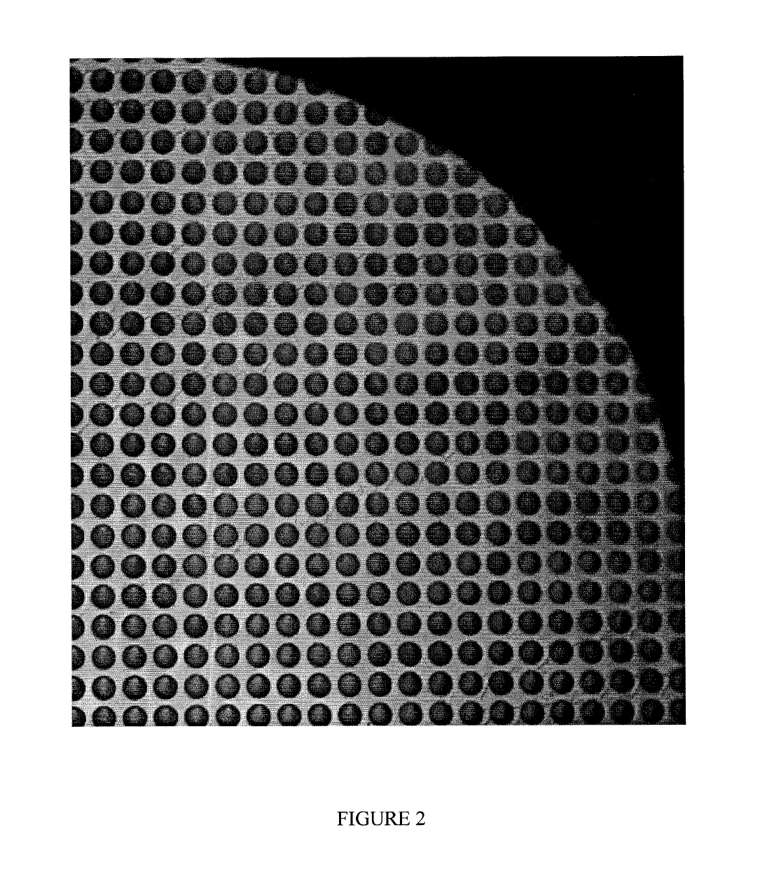

The cladding plate structure is composed of a highly ordered and precise array of capillary tubes. An example of such an array is shown in FIG. 2. The fully cured and cross-linked cladding structure can be placed in a bath that contains a curable liquid prepolymer, such as a cross-linkable styrene liquid prepolymer. By wicking, active pressure, or both, the liquid rises up in the capillaries to the top of the structure. The bath can be heated, for example up to 10 hours in an oven at low temperature: 50° C., to ensure a slow curing speed, with minimal radial shrinkage of the core material in each capillary. The space created by the few percent shrinkage of the curing prepolymer can he filled up by monomer, which slowly becomes fully cross-linked, polymerized, and/or cured. After the first curing, a second high temperature curing step can be used, such as 80° C. for 24 hours, to totally cure and stabilize the core/clad structure. This fabrication method can result in a plate where the core material is fully cured and in good optical contact with the cladding structure.

The structure can be allowed to slowly cool to room temperature and then mounted on a high speed rotary polishing machine. The large faces of the fully cured, plastic fiber optic plate structure can be cut and polished with a diamond tool.

In many applications of fiber optic plates and structures, the so called numerical aperture, NA, of the fibers is critical to their successful operation. The definition of this quantity is given

NA=v(n_{core}²−n_{clad}²)=sin(θ)

where n_{core} and n_{clad} are the refractive indices of the core and cladding polymers of the fiber. The angle theta is termed the maximum acceptance angle of light incident on the end of the fiber. Specifically, the angle theta is the maximum angle at which light incident on the end surface of the fiber can be successfully transmitted into the fiber. Clearly, it is desirable to have the fiber be able to transmit light incident at all angles up to 90 degrees. This corresponds to NA=1.0. In general, for a uniform angular distribution of light incident on the end of the fiber, the light accepted and transmitted by the fiber is proportional to the square of NA. Table 1 shows the NA and intensity of transmitted light by a fiber optic plate or device as a function of choice of materials.

TABLE 1
Relationship of material selection and transmitted
light intensity of Fiber Optic Plate Structure

| | | | Transmitted |
|---|---|---|---|
| Material Selected | | | Light |
| Core/Cladding | Refractive Index | NA | Intensity (NA²) |
| Polystyrene/ | 1.59/1.49 | 0.55 | 0.31 |
| Polymethylmethacrylate | | | |
| Polystyrene/ | 1.59/1.41 | 0.73 | 0.54 |
| Poly Trifluoromethacrylate | | | |
| Polytribromostyrene/ | 1.70/1.36 | 1.0 | 1.0 |
| Polyheptafluoromethacrylate | | | |

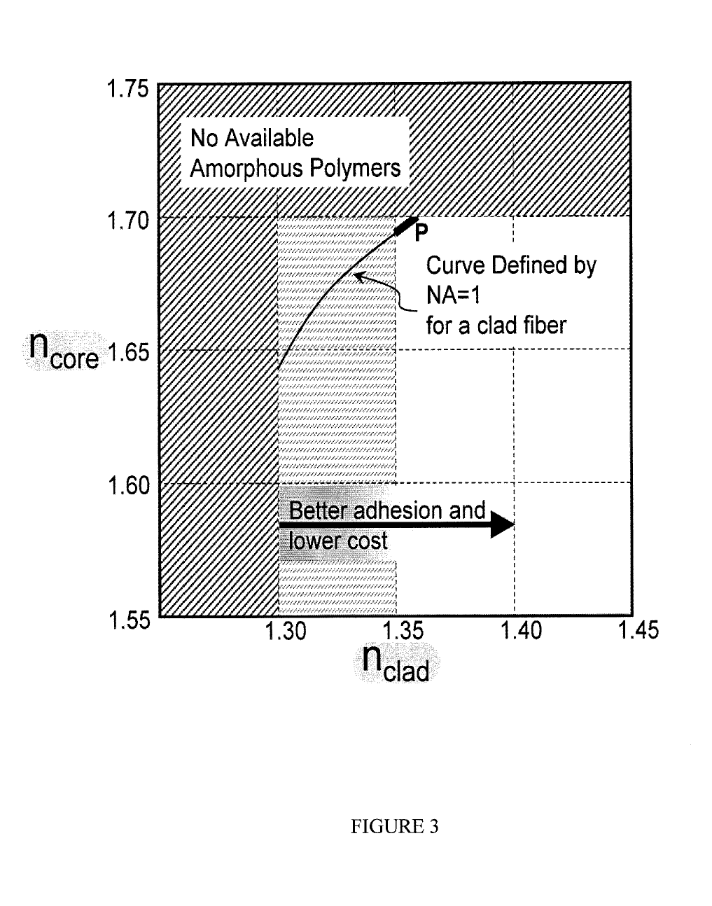

In addition to the importance of achieving high NA for maximum light intensity, the spatial resolution of the image arriving at the back of the fiber optical device is also improved with high NA. The reason for this is that for NA less than one, any light entering the fiber at large enough angles cannot be contained in the fiber and, as a result, traverses out the side of the fiber and enters an adjacent fiber. This leads to a loss of both spatial resolution and contrast in the transmitted image. This reduction of image resolution produces lower signal to noise ratio of the microarray reader. The correlation between core and cladding refractive indices for a fiber with the desired NA of unity is shown in FIG. 3.

Embodiments of the invention can have NA≧0.95, NA≧0.98, NA≧0.99, NA≧0.995, and/or NA≧0.999. Achieving unity numerical aperture is particularly important for the most demanding applications involving fiber optic devices. An example of this type of application is single-molecule real-time genetic sequencing using the fluorescent light generated by any sequencing reaction process. The correlation between core and cladding refractive indices to achieve a numerical aperture of 1.0 is shown. An NA of 1.0 can most economically be achieved in the region indicated by P, where n_{clad} is greater than or equal to 1.35 and n_{core} is less than or equal to 1.70. The adhesion between the core and cladding materials is maximized in the P region where the fluorination of the cladding is as small as possible consistent with achieving an NA=1.

In one embodiment of the invention, polytribromostyrene can he polymerized to form fiber core material and provide good optical transmission with a refractive index of 1.70. When combined with polyheptafluoromethacrylate acting as the cladding material, this new core material creates fiber optic plates and devices with numerical aperture of unity.

In another embodiment of the invention, the material forming the core/cladding structure is polystyrene/polyheptafluormethacrylate. The cladding polymer is made to contain an opaque additive, such as carbon black, at a concentration in the range 0.0001% to 0.01% wt/wt. There is negligible optical attenuation of the light by the cladding material for the light being guided by a fiber. On the other hand, large angle light, which is beyond the angle of internal reflection in the fiber, is attenuated as it traverses a number of cladding wall thicknesses. This type of structure ensures that optical cross talk between fibers is reduced, if not eliminated.

In another embodiment of the invention, the core cladding structure materials are polystyrene/polymethylmethactylate. The fiber core diameter is 40 microns and the pitch of the fiber axes is 50 microns. It has been found this 2D array of fibers transmits and guides ultrasound energy in each fiber with little leakage of energy between fibers. Internal reflection of the ultrasound energy at the core cladding interface is due to the different speeds of ultrasound in the two materials. This type of plate can be used in array-based photoaccoustic spectrography, for example U.S. Pat. No. 6,870,626 titled “Array-based Photoaccoustic Spectroscopy”. In addition, the plate can be used in biometric applications where ultrasonic finger print imaging is performed.

Although embodiments of the present invention and corresponding advantages have been described in detail, it should be understood that various changes, substitutions, and alterations can be made herein without departing from the spirit and scope of the invention as defined by the appended claims. Moreover, the scope of the present application is not intended to he limited to the particular embodiments of the process, machine, manufacture, composition of matter, means, methods and/or steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may he utilized in accordance with embodiments of the present invention. Accordingly, the appended claims are intended to include within their scope such processes, machines, manufacture, compositions of matter, means, methods, or steps.

### EXAMPLES

### Example 1

### Fabrication of Photo Polymeric Fiber Optic Plate

An exemplary apparatus for fiber optic device fabrication is shown in FIG. 1. The photomask is supported by brackets mounted on the optical table. The elevator is attached to a Z-stage micropositioner from Newport. A miniature stepper motor based actuator, Newport, Model TRA25PPD is used to move the elevator vertically under computer control. The minimum incremental motion is 0.1 micron, and the maximum speed is 400 microns/second. The unidirectional repeatability is 2 microns and the backlash, 5 microns, is repeatable to 2 microns. The axial load capacity, 60 N, is adequate to move the elevator through the photocurable liquid while carrying the growing load of the device being fabricated. The collimated flood exposure source is able to provide up to 38 mW/cm² at the upper surface of the mask. The photocurable liquid is maintained in an inert gas atmosphere during the fabrication process.

Initially, the elevator is raised to a height such that the gap between the elevator and the chrome pattern on the bottom of the mask is 15 microns. This gap distance is measured by three precision micrometers, which also establish the coplanarity of the mask and elevator. The level of photocurable liquid is made to be at least 1 mm higher than the bottom of the mask. A typical 5-30 second exposure is made to effect substantial curing of the 15 micron thick photocurable liquid. The shutter is closed under computer control and the elevator is lowered by 15 microns. The shutter of the illuminator is opened under computer control and a second identical exposure is made. This process is repeated until the requisite thickness of the fiber cladding structure has been fabricated. A 1 mm thick cladding plate can be made in approximately five minutes. This is the standard thickness of a 1″×3″ microscope slide. The 6″×6″ exposure area of the apparatus could therefore fabricate the cladding structure of 12 fiber optic microscope slides simultaneously. The cladding structure is washed in an appropriate solvent and exposed to a final curing cycle.

The fully cured and cross-linked cladding structure is placed in a fixture located in a bath that contains a cross-linkable high refractive index liquid prepolymer and, optionally, 1 to 15% monomer. By wicking, active pressure, or both, the liquid rises up in the capillaries to the top of the structure. The bath is heated for 10 hours in an oven containing an inert gas at low temperature: 50° C. This slow curing speed produces minimal radial shrinkage of the core material in each capillary and the few percent shrinkage volume of the curing prepolymer is continuously made up by monomer which slowly becomes fully cross-linked. After the first curing, a second high temperature curing step is used: 80° C. for 24 hours. This stage produces a totally cured and stabilized core/clad structure. This fabrication method assures that the core material is fully cured and in good optical contact with the cladding structure. The plate is then cut and polished using a diamond tool.

A 10 square centimeter fiber optic plate was fabricated in the above way with a nominal 6 micron pitch between fiber core axes and core diameter of 4 microns. Using a microscope, the pitch was measured in a contiguous array of 10,000 fibers to have a uniformity of 6.1+/−0.3 microns. Similar measurements on a glass fiber optic plate gave a pitch uniformity of 6.2+/−2.4 microns. Accordingly, the lithographically fabricated structure has adequate uniformity to perform readout from high throughput, dense microarrays for gene sequencing and protein diagnostics. In these lithographically produced arrays, the light sources have pitch uniformity similar to that measured for the plastic fiber optic plate.

### Example 2

### Microfabrication of Microcapillary Array Plates

A microcapillary array is composed of hundreds of thousands, or millions of uniform diameter hollow tubes. When these tubes are partially filled with liquids, an assortment of bioactive probes can be inserted by an array spotter into the tubes. In some cases, fluorescent light may be emitted. Some of the light can be reflected from the low refractive index material forming the walls of the tubes and be detected to provide information on the reaction. There is an ease of filling the tubes by capillary action, and similarly, the flow through nature of the plate permits easy removal of the liquids after the bioactive or chemical probe reactions have been studied. In essence, one million test tube experiments can be conducted in parallel.

The fabrication of a microcapillary plate is performed as follows: The core/cladding material can be polystyrene/polyheptafluoromethacrylate and the plate is initially made following the procedure described in Example 1. The plate faces are cut and polished as before. The cutting and polishing process is much more efficient with the presence of core material in the plate. The plate is then placed in an ultra-sonic bath containing solvent, such as toluene. The polystyrene is highly soluble and is rapidly dissolved in a few minutes. The highly fluorinated cladding structure has low solubility in the solvent and remains as a strong structure. The plate is dried and heated to eliminate residual solvent. Microcapillary plates with tube diameters in the range 3 to 300 microns can be made with large area up to 6″×6″.

### Example 3

### Microfabrication of a Microwell Fiber Optic Arrays

This type of plate is made in a similar manner as the microcapillary plate described in Example 2 above. There are two modifications in the fabrication process. First, the plate structure is placed in the ultra-sonic bath in such a way that only one face of the plate enters the solvent. Secondly, the length of time of the plate in the solvent is relatively short and adequate to only dissolve a short length of the core material and thereby produce a well. Typically the depth of the well is similar to the diameter of the fiber. The dimensions are able to he customized for specific applications. The structure can be equivalent to a very large number of “short test tubes” with their walls formed by the cladding structure and the bottom surface is the end of a plastic optical fiber. The “far end” of the optical fibers in the Microwell Array plate can be directly coupled to a CCD for efficient read out of the light emitted by the contents in each well. The Microwell Array plate with well diameters, for example in the range 3 to 300 microns, can be made in large areas up to 6″×6″ or even 12″×12″ with larger flood UV source illuminators.

### Example 4

### Microfabrication of Fiber Optic Plate with Large Microwells

In Example 3 above, each microwell was interrogated by a single optical fiber. There are applications where it is desired to interrogate a well with a number of optical fibers. Such an application may be the study of the interactions between a number of cells in a colony growing in wells under a variety of different ambient conditions.

This type of plate is made in a similar manner to that described in Example 1 above. The fabricated plate is put back into the micro fabrication illuminator by placing it directly on top of the elevator. An optically opaque photocurable liquid is used in the bath. A photomask is used which produces a new cladding structure on the top surface of the plate. The new cladding structure provides holes whose diameter is much larger than an individual fiber of the underlying plate. The typical range of the ratio of hole diameter to optical fiber diameter is 3 to 1 up to several 1000 to 1. The fabrication of the walled cladding structure progresses until the desired height of the walls has been reached. Typical wall height is in the range of 10 to 1000 microns. Wall thickness is typically 10% of the core size. Once the plate has been fabricated, it is processed as before by washing out low molecular weight moieties and baking in an oven to fully cure the walls. No further processing is required. The important benefit of this type of “Large Microwell Fiber Optic Plate” is it provides a high spatial resolution investigation of fluorescent light output from a colony of biological cells or chemical material contained in each large microwell. That information can be simultaneously obtained for each colony in different wells containing different solutions and environments.

### Example 5

### Microfabrication of Microtiter Plates

Microtiter plates are plastic sample holders used in biology or chemistry research. The microtiter plate standard was formalized by the Society for Biomolecular Screening in 1996. The specifications have been published by the American National Standards Institute (ANSI). The plate typically has 6, 12, 24, 96, 384, or even 1536 sample wells arranged in a 2:3 rectangular matrix. The Standard governs well dimensions (e.g., diameter, spacing, and depth) as well as plate properties (e.g., dimensions and rigidity). These plates can be made as described in Example 4 above, to the specific dimensions prescribed by the ANSI. The advantage of the microtiter plates made by the present invention is that their direct CCD readout through the bottom plate provides high resolution and high optical collection efficiency. A Microtiter Plate Reader with this design is robust, lower cost, and most applicable to point of care diagnostic testing.

### Example 6

### Microfabrication of a 180 Degree Optical Inverter

Fiber optical inverters made of glass have been extensively used in image intensifiers for night vision purposes. When employed by pilots in headgear that must be worn for extended time periods, the weight of the image intensifier frequently causes extreme fatigue and reduced performance. A significant component of the weight of the intensifier is the weight of the glass image inverter. A plastic image inverter can be fabricated to provide improved performance due to reduced image distortion and improved ergonomics due to a factor of three reduced weight.

Typical dimensions of glass image inverters are 1″-2″ diameter and 1″-2″ long. Typical fiber diameters in an inverter are in the range 3 to 6 microns. The polymeric microfabrication of a typical 1″ diameter optical inverter with 6 micron diameter fibers is described. Using this microfabrication process the length of the image inverter can be made 0.75″ long, rather than the 1″ length required for the glass product. The combination of reduced density by a factor 2.4 and reduced length produces a highly advantageous factor of 3 reduced weight.

This type of plate is initially made in a similar manner to the microcapillary plate described in Example 2 above. However, after each 15 micron ultra violet exposure, the mask is rotated about its center by an angle equal to 2.5 mrad. The stepped curve of the growing structure introduces a negligible effect on the efficiency of guiding the light within the structure. Alternatively, it is possible to rotate the mask continuously and eliminate this step like nature of the optical structure.

In a preferred embodiment of this application, it has been found possible to leave the mask fixed and rotate each of a plurality of small platforms on the moving elevator and thereby simultaneously produce a large number of optical inverters.

1. A method for fabricating a polymeric structure, comprising:
exposing a first polymerizable polymer precursor to a patterned beam of light to form a first patterned polymeric layer;
positioning additional first polymerizable polymer precursor adjacent to the first patterned polymeric layer such that exposing the additional first polymeric polymer precursor forms an additional patterned polymeric layer on top of the first polymeric layer;
exposing the additional first polymeric polymer precursor to form the additional patterned polymeric layer on top of the first polymeric layer, wherein the first patterned polymeric layer and the additional patterned polymeric layer form a polymeric structure.

2. The method according to claim 1, further comprising:
positioning further additional first polymerizable polymer precursor adjacent the additional patterned polymeric layer such that exposing the further additional first polymeric precursor forms a further additional patterned polymeric layer on top of the polymeric structure to increase a thickness of the polymeric structure; and
exposing the further additional first polymeric precursor to form a further additional patterned polymeric layer on top of the polymeric structure to increase the thickness of the polymeric structure.

3. The method according to claim 2, further comprising:
a. positioning further additional first polymeric precursor adjacent the further additional patterned polymeric layer such that exposing the further additional first polymeric precursor forms a further additional patterned polymeric layer on top of the polymeric structure to enlarge the polymeric structure; and
b. exposing the further additional first polymeric precursor to form a further additional patterned polymeric layer on top of the polymeric structure to increase the thickness of the polymeric structure.

4. The method according to claim 3, further comprising:
repeating a and b until a desired thickness of the polymeric structure is reached.

5. The method according to claim 4, wherein exposing a first polymerizable polymer precursor to a patterned beam of light to form a first patterned polymeric layer comprises:
exposing a bath of the first polymerizable polymer precursor located on top of a moveable elevator to the patterned beam of light to form the first patterned polymeric layer,
wherein positioning additional first polymerizable polymer precursor adjacent to the first patterned polymeric layer such that exposing the additional first polymeric polymer precursor forms an additional patterned polymeric layer on top of the first polymeric layer comprises:
lowering the movable elevator in the bath of the first polymerizable polymer precursor such that exposing the bath of the first polymerizable polymer precursor with the patterned beam of light forms the additional patterned polymeric layer on top of the first polymeric layer;
wherein positioning further additional first polymerizable polymer precursor adjacent to the additional patterned polymeric layer such that exposing the further additional first polymeric precursor forms a further additional patterned polymeric layer on top of the polymeric structure to increase a thickness of the polymeric structure comprises:
lowering the movable elevator in the bath of the first polymerizable polymer precursor such that exposing the bath of the first polymerizable polymer precursor with the patterned beam of light forms the further additional patterned polymeric layer on top of the polymeric structure,
wherein positioning further additional first polymeric precursor adjacent the further additional patterned polymeric layer such that exposing the further additional first polymeric precursor forms a further additional patterned polymeric layer on top of the polymeric structure to increase the thickness of the polymeric structure comprises:
lowering the movable elevator in the bath of the first polymerizable polymer precursor such that exposing the bath of the first polymerizable polymer precursor with the patterned beam of light forms the further additional patterned polymeric layer on top of the polymeric structure.

6. The method according to claim 5, wherein the polymeric structure has at least one void region, further comprising filling at least a portion of one or more of the at least one void region with a second polymerizable polymeric precursor; and
polymerizing the second polymerizable polymeric precursor.

7. The method according to claim 6, wherein filling at least a portion of one or more of the at least one void region with the second polymerizable polymeric precursor comprises filling the at least one void region with the second polymerizable polymeric precursor.

8. The method according to claim 7, wherein filling the at least one void region comprises placing the polymeric structure in a heated bath of the second polymerizable polymeric precursor, wherein the second polymerizable polymeric precursor fills the at least one void region of the polymeric structure and is polymerized.

9. The method according to claim 5, further comprising:
washing the polymeric structure to remove unpolymerized material; and
heating the polymeric structure to achieve further polymerization.

10. The method according to claim 8, wherein placing the polymerized structure in a heated bath comprises controlling a temperature cycle of the heated bath via computer.

11. The method according to claim 8, further comprising:
polishing a first end and a second end of the polymeric structure.

12. The method of claim 5, wherein the patterned beam of light comprises light having a wavelength less than 450 nm.

13. The method of claim 5, wherein the patterned beam of light comprises light having a wavelength less than 400 nm.

14. The method of claim 5, wherein the patterned beam of light is formed by traversing light through a partially transparent mask.

15. The method of claim 14, wherein the first polymerizable polymer precursor is in direct contact or in proximal contact with the partially transparent mask.

16. The method of claim 14, wherein a coplanarity of the partially transparent mask with respect to the elevator is controlled to have angular deviations of coplanarity less than 10⁻³ radians.

17. The method according to claim 16, wherein the coplanarity of the partially transparent mask and the elevator is controlled to have angular deviations of coplanarity less than 2×10⁻⁴ radians.

18. The method of claim 14, wherein a gap between the elevator and the partially transparent mask is controlled to be less than 100 microns during providing the patterned beam of light to form the first patterned polymeric layer.

19. The method according to claim 18, wherein the gap is controlled to be less than 50 microns during providing the patterned beam of light to form the first patterned polymeric layer.

20. The method according to claim 18, wherein the gap is controlled to be less than 30 microns during providing the patterned beam of light to form the first patterned polymeric layer.

21. The method of claim 5, wherein the first polymerizable polymer precursor is a photocurable liquid composition.

22. The method according to claim 21, wherein the photocurable liquid composition comprises a mono or multi-functional monomer.

23. The method according to claim 21, wherein the photocurable liquid composition is a homo- or co-polymer.

24. The method according to claim 21, wherein the photocurable liquid composition comprises a photo-initiator.

25. The method according to claim 21, wherein the photocurable liquid composition has dispersed within it a visible light absorbing chemical dopant.

26. The method according to claim 25, wherein the light absorbing chemical dopant controls a curing depth of the photocurable liquid composition.

27. The method according to claim 21, wherein the photocurable liquid composition has dispersed within it a light absorbing chemical dopant, wherein the light absorbing chemical dopant controls cross-talk of light from one of a plurality of component elements of the polymeric structure to another of the plurality of component elements.

28. The method of claim 5, wherein the polymeric structure is washed in a solvent after removing the polymeric structure from the bath of the first polymerizable polymeric precursor.

29. The method according to claim 28, wherein the solvent comprises a liquid selected from the group consisting of methanol, methyl ether ketone, and combinations thereof.

30. The method according to claim 28, wherein the polymeric structure is washed in an ultra-sonic bath.

31. The method of claim 9, wherein heating the polymeric structure comprises placing the polymeric structure in a vacuum oven at a temperature of at least 40° C. for at least 10 hours, followed by a temperature of at least 60° C. for at least 24 hours.

32. The method of claim 8, wherein placing the polymeric structure in a heated bath of the a second polymerizable polymeric precursor comprises placing the polymeric structure in a heated ultrasonic bath holding the second polymerizable polymeric precursor.

33. The method according to claim 8, wherein the second polymerizable polymeric precursor is a mono or co-polymeric material.

34. The method according to claim 8, wherein once the second polymerizable polymeric precursor fills the at least one void region in the polymeric structure, further comprising raising a temperature of the heated bath to at least 50° C. for at least 10 hours; and raising the temperature of the heated bath to at least 70° C. for at least 24 hours.

35. The method according to claim 8, further comprising:
wicking the second polymerizable polymer precursor into the at least one void region.

36. The method according to claim 8, further comprising:
applying pressure to fill the at least one void region with the second polymerizable polymer precursor.

37. The method of claim 31, wherein the second polymerizable polymeric precursor has been previously polymerized to a molecular weight up to 5000 to reduce subsequent contraction.

38. The method according to claim 8, wherein the second polymerizable polymeric precursor comprises a mono- or multi-functional monomer.

39. The method according to claim 8, wherein the second polymerizable polymeric precursor comprises a thermal activated initiator and a monomer, wherein the monomer is 80% or less of the second polymerizable polymer precursor.

40. The method according to claim 8, wherein the polymerized second polymerizable polymeric precursor is a cross-linked polymer having a refractive index of at least 1.49.

41. The method according to claim 40, wherein the polymerized second polymerizable polymeric precursor is a cross-linked polymer having a refractive index of at least 1.59.

42. The method according to claim 40, wherein the polymerized second polymerizable polymeric precursor is a cross-linked polymer having a refractive index of at least 1.7.

43. The method according to claim 40, wherein the cross-linked polymer comprises one or more essentially transparent polymers.

44. The method according to claim 40, wherein the cross-linked polymer comprises mono or multi-functional monomers or co-monomers of one or more of the group consisting of: polymethylmethacrylate, polystyrene, and polytribromostyrene.

45. An apparatus for fabricating a three dimensional polymeric structure, comprising:
a light source, wherein the light source provides a beam of light;
a mask, wherein when the beam of light passes through the mask a patterned beam of light is created;
a photocurable liquid, wherein the beam of light and the mask are positioned such that the patterned beam of light is incident on the photocurable liquid,
a platform, wherein the platform is moveable relative to a bottom surface of the mask, wherein at least a portion of the photocurable liquid is positioned between the platform and the bottom surface of the mask, wherein when the patterned beam of light is incident on the photocurable liquid a portion of the photocurable liquid corresponding to a beam pattern of the patterned beam of light is polymerized.

46-68. (canceled)

69. A product, comprising:
a three dimensional polymeric structure having a plurality of component elements positioned in a two-dimensional array at a uniform interelement distance of less than 100 microns.

70-91. (canceled)
